(19) United States
(12) Patent Application Publication
(10) Pub. No.: US 2011/0174355 A1
(43) Pub. Date: Jul. 21, 2011

(54) SOLAR CELL AND SOLAR CELL MODULE WITH ONE-SIDED CONNECTIONS

(75) Inventors: Daniel Biro, Freiburg (DE); Nicola Mingirulli, Berlin (DE); Florian Clement, Freiburg (DE); Ralf Preu, Freiburg (DE); Robert Woehl, Freiburg (DE)

(73) Assignee: Fraunhofer-Gesellschaft Zur forderung Der Angewandten Forschung E.V., Munchen (DE)

(21) Appl. No.: 13/061,215

(22) PCT Filed: Aug. 25, 2009
(86) PCT No.: PCT/EP2009/006138

§ 371 Date: Apr. 1, 2011

(30) Foreign Application Priority Data
Aug. 30, 2008 (DE) 10 2008 044 910.5

(51) Int. Cl. H01L 31/05; H01L 31/0224

(52) U.S. Cl. 136/244; 136/256

(57) ABSTRACT

A solar cell, in particular for connecting to a solar cell module, including at least one metallic base contact, at least one metallic emitter contact (5) and a semi-conductor structure having at least one base area and at least one emitter area (3). The base area and emitter area (2,3) are at least partially adjacent to each other forming a pn-junction, the base contact (6) being connected in an electrically conductive manner to the base area (2), the emitter contact (5) being connected in an electrically conductive manner to the emitter area (3), and the solar cells being arranged on the contact side (1) as a base and emitter contact (6,5). Essentially, the solar cell includes several metallic emitter contacts which are connected in an electrically conductive manner to the emitter area (3) and several metallic base contacts which are connected in an electrically conductive manner to the base area (2). The emitter contacts (5) do not have an electrically conductive connections among each other on the side facing away from the emitter area (3) and the base contacts do not have an electrically conductive connections on the side facing away from the base area (2). A solar cell module including at least two solar cells is also provided.

### BACKGROUND

The invention relates to a solar cell, in particular, to the interconnection in a solar-cell module.

Solar cells typically consist of a semiconductor structure that has a base and an emitter area. In the semiconductor structure, light is typically coupled via the front side of the solar cell, so that after absorption of the coupled light, a generation of electron-hole pairs takes place in the solar cell. A pn-junction is formed between the base and emitter area, with the generated charge-carrier pairs being separated at this pn-junction. Furthermore, a solar cell comprises a metallic emitter contact and also a metallic base contact that are each connected in an electrically conductive way to the emitter and to the base, respectively. By means of these metallic contacts, the charge carriers separated at the pn-junction can be discharged and thus fed to an external circuit or to an adjacent solar cell in the case of module interconnection.

Different solar-cell structures are known, wherein the present invention relates to those solar-cell structures in which both the metallic emitter contact and also the metallic base contact are arranged on one contacting side of the solar cell, typically the back side of the solar cell. This stands in contrast to standard solar cells in which typically the metallic emitter contact lies on the front side and the metallic base contact lies on the back side of the solar cell.

Solar cells in which the metallic emitter contact and base contact are arranged on one contacting side have the advantage that they can be contacted on one side, i.e., they can be connected to other solar cells in a module or to an external circuit by interconnections on only one side of the solar cell.

Such solar cells that can be contacted on one side typically have, on the back side, comb-like, interdigitated metallization structures, wherein a first comb-like metallization structure is connected in an electrically conductive way to the emitter area and the second metallization structure engaging in the first metallization structure like a comb is connected in an electrically conductive way to the base.

The positive and also the negative charge carriers are guided via the comb-like metallization structures laterally, that is, parallel to the contacting side of the solar cell, to one or more collection points of the metallization structures and tapped there by means of cell connectors or other contacting types.

Such a solar-cell structure is described, for example, in [1] (see “References”).

### SUMMARY

Starting from here, the present invention is based on the objective of creating a solar cell that can be contacted on one side and a corresponding solar-cell module, wherein the potential for optimization with respect to the efficiency of the solar cell relative to the previously known solar-cell structures should be increased and the failure probability of the solar cell and especially of the solar-cell module due to external influences should be reduced.

This task is achieved by a solar cell and a solar-cell module according to the invention. Advantageous embodiments of the solar cell and advantageous embodiments of the solar-cell module are described in detail below and in the claims.

The solar cell according to the invention comprises at least one metallic base contact, at least one metallic emitter contact, and also a semiconductor structure. The semiconductor structure has at least one base area and at least one emitter area.

The base area and emitter area are arranged bordering each other at least partially, so that a pn-junction is formed between the base area and emitter area at least in the boundary area.

The base area and emitter area have opposite doping. Doping types are the n-doping and the opposite p-doping.

Typically, in the solar cell according to the invention, the base area is n-doped and the emitter area is p-doped. An inversion of the doping types also lies within the scope of the invention, that is, a p-doped base and an n-doped emitter.

The semiconductor structure can here consist of a single silicon wafer that has an underlying doping as the base doping and, for example, in a sub-area close to the surface, an emitter with a doping type opposite the doping type of the base doping.

The emitter could be generated, for example, by diffusion of a dopant.

Similarly, other types of semiconductor structures for the construction of a solar cell also lie in the scope of the invention, for example, multi-layer systems in which, for the production on a first layer, a second layer is deposited with different doping, so that a pn-junction or hetero-structures are constructed at the layer boundary between the first and second layer.

The base contact is connected in an electrically conductive way to the base area and the emitter contact is connected in an electrically conductive way to the emitter area.

In the sense of the present application, in the phrase “connected in an electrically conductive way,” those currents or recombination events are neglected that occur at or above a pn-junction. Thus, in the sense of the present application, the emitter area and base area are not connected in an electrically conductive way via the pn-junction and accordingly, the emitter contact is also not connected in an electrically conductive way to the base contact.

In the sense of this application, the phrase “base contact” designates a metallic structure that is connected in an electrically conductive way to a base area. Accordingly, in the sense of this application, “emitter contact” designates a metallic structure that is connected in an electrically conductive way to an emitter area. For electrical connection to the emitter area, an emitter contact has a continuous contact surface between the emitter contact and emitter area and likewise a base contact for the electrical connection to the base area has a continuous contact surface between the base contact and base area.

It is essential that the solar cell according to the invention comprises several metallic emitter contacts that are each connected in an electrically conductive way to at least one emitter area and likewise several metallic base contacts that are each connected in an electrically conductive way, in turn, to at least one base area.

Here, it lies within the scope of the invention that several emitter contacts are connected in an electrically conductive way to an emitter area. Similarly, it lies in the scope of the invention that the solar cell has several emitter areas, wherein each emitter area is connected in an electrically conductive way to one or to several emitter contacts. A corresponding situation applies to the base contacts and the base areas.

Furthermore, it is essential that the emitter contacts are not connected in an electrically conductive way to each other or only via an emitter area and likewise the base contacts are not connected in an electrically conductive way to each other or only via a base area.

If the solar cell according to the invention is constructed such that it has several emitter areas, then the condition named above means that for each arbitrary pair of two emitter contacts it is valid that the two emitter contacts are not connected in an electrically conductive way or only via an arbitrary emitter area. A corresponding situation applies to the base contacts, as long as the solar cell according to the invention has several base areas.

A typical, previously known solar cell that can be contacted on one side comprises, as described before, comb-like, interdigitated metallization structures on the back side, with these structures being connected in an electrically conductive way on one hand to the base and on the other hand to the emitter. Here it is known that an insulating layer that has several recesses is arranged between the metallic contacting structures and the semiconductor surface, with the metallic structures being led through these recesses for contacting the semiconductor lying underneath. In this previously known solar cell, a plurality of emitter contact areas is connected in an electrically conductive way on the semiconductor surface of the emitter area by a metallic structure and similarly a plurality of base contact areas on the corresponding semiconductor surface of the base area are connected in an electrically conductive way by means of another metallic structure.

The solar cell according to the invention differs from this configuration in that the emitter contacts have no electrically conductive connection among each other on the side facing away from the emitter area and the base contacts likewise have no electrically conductive connection on the side facing away from the base area. Thus, in particular, the emitter contacts are not connected in an electrically conductive way among each other by a metallic contact structure and the same applies to the base contacts.

The invention is based on the realization of the applicant that, for the optimization and creation of a solar-cell structure that is not sensitive relative to disruptive influences, the lateral current flow of charge carriers outside of the semiconductor structure is not to be performed in the metallic contact structures of the solar cell, but instead in the external contact structures that are not an integral component of the solar cell, such as, for example, the cell connectors in the module interconnection of the solar cells.

In this way, the advantage is produced that emitter contacts can be optimized only with respect to the contacting properties of the corresponding semiconductor area, that is, in particular, with respect to the contact resistance and a low surface recombination rate in the area of the contacted semiconductor surface and, on the other hand, the lateral current flow takes place outside of the semiconductor structure in additional connection elements, such as, for example, the cell connectors in module interconnection, so that these can be optimized separately for lowest possible losses, such as, for example, ohmic intermediate resistance losses, for the lateral charge-carrier transport.

In addition, the solar cell according to the invention has the advantages that for an external effect that leads to a fracture in the semiconductor structure, as a rule the electrically conductive connection of the emitter contacts to the external connection structures, such as, for example, the cell connectors, remain intact, so that even the areas of the solar cell separated electrically by the fracture in the semiconductor can still contribute to the power generation.

In the solar cells noted above that can be contacted on the back side, a fracture in the semiconductor structure typically likewise leads to a fracture of the comb-like, interdigitated metallic contacting structures on the contacting side of the solar cell, so that the lateral current transport is interrupted, on one hand, by the fracture in the semiconductor structure and, on the other hand, by the fracture in the comb-like metallic connection structure and thus at least parts of the solar cell can no longer contribute to the power generation.

The contacting side is advantageously the back side of the solar cell. This allows a simple module interconnection, as well as the reduction of shading losses on the front side of the solar cell by metallic structures.

Advantageously, the solar cell therefore has a plurality of emitter contacts and/or base contacts according to the construction according to the invention, in particular, at least 10, advantageously at least 100, furthermore, at least 1000 emitter contacts and/or base contacts.

Advantageously, the emitter and the base contacts are arranged and constructed such that the emitter contacts and base contacts are not interdigitated according to the following condition:

The solar cell according to the invention is advantageously constructed such that the emitter contacts are arranged and constructed such that, around each emitter contact, an imaginary convex surface can be defined that completely contains the emitter contact and contains no base contact and also no sub-area of a base contact, and the base contacts are each arranged and constructed such that, around each base contact, an imaginary convex surface can be defined that completely contains the base contact and contains no emitter contact and also no sub-area of an emitter contact.

A surface is then convex when it is applicable for two arbitrary points of the surface that the straight-line connection between these two points lies completely within the surface.

The previously mentioned condition thus defines an advantageous construction of the solar cell according to the invention in which the emitter contact and base contact are not interdigitated. For a construction of emitter contacts and base contacts engaging one in the other there is the risk that a fracture of a solar cell leads to a fractured piece in which there is a contact of one polarity and parts of a contact of the opposite polarity engaging with this contact. Such fractured pieces suffer a loss in efficiency and thus reduce the total efficiency of all fractured pieces. This is ruled out in the mentioned condition.

In the sense of this application, the phrase “completely” with reference to contacts means that the entire metallic contact structure of the contact lies within the imaginary circle or the imaginary surface and not, for example, only a center point of the metallic contact structure.

Advantageously, emitter contacts and/or base contacts are constructed and arranged such that a sufficient density of the contacts is reached on the contacting side of the solar cell. In this way, intermediate resistance losses within the solar cell due to the direct routing of charge carriers are reduced.

The emitter contacts and base contacts are therefore advantageously arranged and constructed such that for each emitter contact it is applicable that at least this complete emitter contact and at least one complete base contact lie within an imaginary circle with diameter d₁. An arbitrary emitter contact thus fulfills the condition that it lies completely in an imaginary circle with diameter d₁ around this emitter contact and also at least another emitter contact lies completely in this imaginary circle. Accordingly, for each base contact it is applicable that at least this complete base contact and at least one complete emitter contact lie within an imaginary circle with diameter d₁.

The diameter d₁ is here selected such that a condition according to Formula 1 is fulfilled:

d₁≦k₁·\sqrt{Aₖ} (Formula 1)

with a scaling factor k₁ and the surface area A_{K} [cm²] of the contacting side of the solar cell. By specifying the scaling factor k₁, for a given surface area of the contacting side A_{K}, an upper limit for the diameter d₁ is thus given and thus a minimum density for the previously mentioned contact arrangement, as well as a maximum size for the contact construction.

Studies of the applicant have resulted in that the scaling factor is selected as k₁=0.13, advantageously k₁=0.06, especially k₁=0.03, more advantageously k₁=0.014. In this way, a sufficient density of the emitter contacts and base contacts is guaranteed.

The advantageous constructions of the solar cell according to the invention according to the condition with respect to Formula 1 and according to the following conditions with respect to Formulas 2, 3, and 4 are thus such that an imaginary circle with the specified properties for the specified contacts or contact groups must absolutely be able to be defined.

Furthermore it is advantageous to guarantee a sufficient density between the contacts of one polarity, i.e., between the emitter contacts on one side and/or the base contacts on the other side.

Advantageously, the emitter contacts are therefore arranged and constructed such that, for each emitter contact, at least this complete emitter contact and at least one additional complete emitter contact lie within an imaginary circle with diameter d₂.

Alternatively or additionally it is advantageous that the base contacts are arranged and constructed such that, for each base contact, at least this complete base contact and at least one additional complete base contact lie within an imaginary circle with diameter d₂.

For the previously named conditions with respect to the emitter contacts among each other and/or the base contacts among each other, the diameter d₂ is selected such that a condition according to FIG. 2 is fulfilled:

d₂≦k₂·\sqrt{Aₖ} (Formula 2),

with a scaling factor k₂ and the surface area A_{K} [cm²] of the contacting side of the solar cell. Studies of the applicant have resulted in that the scaling factor is advantageously selected as k₂=0.26, preferably k₂=0.13, especially k₂=0.06, more advantageously k₂=0.028.

Advantageously, emitter contacts and base contacts are distributed approximately uniformly across the contacting side of the solar cell according to the invention.

Here it is especially advantageous that the emitter contacts and the base contacts are arranged on the intersection points of an imaginary, right-angle lattice, especially a lattice with square cells. Emitter contacts and base contacts are here arranged such that emitter contacts and base contacts alternate along each line of the imaginary lattice. Thus, this has the result that the four closest neighbors for an emitter contact are each base contacts and vice versa.

Typical solar cells have approximately the shape of a flat right parallelepiped and the contacting side correspondingly has a square shape. Advantageously, the solar cell according to the invention has a square contacting side and the previously described imaginary lattice is arranged such that the lattice lines are at an angle of 45° relative to the edges of the contacting side.

Through this arrangement it is possible to connect to each other either a row of base contacts or, in parallel to this, a row of emitter contacts to a metallization line running parallel to an edge of the contacting side. Thus, in this way, through comb-like, interdigitated cell connectors, a contacting of all of the emitter contacts can be carried out via a first comb-like cell connector and a contacting of all of the base contacts can be carried out via a second comb-like cell connector that is interdigitated with the first cell connector.

It likewise lies in the scope of the invention to arrange the lattice lines at a different angle to the edges of the contacting side.

Furthermore, it lies in the scope of the invention that emitter contacts and base contacts are arranged on the intersection points of an imaginary lattice that has diamond-shaped lattice elements. It likewise lies in the scope of the invention to arrange the emitter contacts and base contacts on two separate lattices, i.e., to provide one imaginary lattice for the emitter contacts and one imaginary lattice for the base contacts.

In order to keep intermediate resistance losses low within the solar cell due to the direct routing of charge carriers, it is advantageous that two adjacent emitter contacts have a distance less than 1 cm, especially less than 5 mm.

The same applies for the base contacts: advantageously the base contacts are arranged such that the distance of two adjacent base contacts corresponds to the previously named conditions.

It likewise lies in the scope of the invention to cover the contacting side of the solar cell essentially by the base contacts and/or the emitter contacts, wherein adjacent contacts are separated from each other by narrow intermediate spaces and thus electrically insulated. In particular, it is advantageous that the intermediate spaces between adjacent contacts equal a maximum of 1 cm, especially 5 mm.

Advantageously, the emitter contacts and the base contacts are constructed such that each contact covers a total surface area of less than 16 mm², advantageously less than 5 mm², especially less than 1 mm², more advantageously less than 0.4 mm². The projection of an arbitrary contact on the contacting side thus covers a surface area less than the listed limits.

In particular, it is advantageous that the emitter contacts and base contacts have approximately circular or approximately square or approximately star-shaped constructions.

In another advantageous embodiment, the contacting side of the solar cell according to the invention is improved with respect to its recombination properties, such that on the contacting side, the semiconductor structure has an electrically non-conductive insulation layer. Advantageously, this insulation layer likewise has passivation properties with respect to the surface recombination of the semiconductor structure. The insulation layer has recesses at the locations of the base contacts and emitter contacts and the base contacts and emitter contacts are arranged on the insulation layer and are led through the recesses of the insulation layer for the electrical contacting of the surface of the semiconductor structure lying underneath.

In this advantageous embodiment, the base contacts and emitter contacts thus penetrate the insulation layer at each of its recesses. The recesses in the insulation layer are advantageously already present before the solar cells are connected to the insulation layer. It likewise lies in the scope of the invention that the insulation layer is arranged on the solar cells first without recesses and the recesses are produced also in the processing step in which the contacts are produced. This is possible, for example, through use of lasers, according to the known method of “Laser Fired Contacts” (LFC), as described in DE 100 46 170 A1. Alternatively, the recesses are produced such that the contacts are first applied to the insulation layer and are heated in a subsequent firing step, so that the insulation layer is penetrated by the contacts and therefore the recesses are produced and the contact connects to the semiconductor in an electrically conductive way.

The contacts are advantageously applied by vacuum deposition, screen printing, sputtering, stencil printing, inkjet printing method, or dispersion. The solar cell according to the invention is suitable, in particular, for production by a screen-printing method, because the dimensions especially of the base contacts are suitable for screen-printing conditions.

Here it is advantageous that the recesses of the insulation layer have a surface area less than 16 mm², advantageously less than 5 mm², especially less than 1 mm², more advantageously less than 0.4 mm², so that the contact surface area of the metallic base contacts and emitter contacts on the semiconductor surface also has a correspondingly dimensioned surface area. On the insulation layer, however, the surface area of the base contacts and emitter contacts can be selected to be larger, without the surface recombination rate of the semiconductor structure on the contacting side being increased in this way. For the simpler contacting of the base contacts and emitter contacts, it is advantageous that the base contacts and emitter contacts on the insulation layer each cover an area with a surface area less than 16 mm², advantageously less than 5 mm², especially less than 1 mm², more advantageously less than 0.4 mm². The contacts advantageously cover an approximately circular or approximately square area or an approximately star-shaped area.

It lies in the scope of the invention to construct the solar cell according to the invention with several base areas and/or several emitter areas, wherein at least one base and one emitter area at least partially bordering this base are constructed according to the structure according to the invention.

In the previously described embodiments of the solar cells according to the invention, the base contacts are connected in an electrically conductive way to each other only via the base area of the semiconductor structure and likewise the metallic emitter contacts are connected only via the emitter area of the semiconductor structure.

In one advantageous embodiment of the invention, the emitter contacts are divided into groups, wherein each group comprises a number of at least 2 and a maximum of 30, especially a maximum of 20, advantageously a maximum of 10 emitter contacts. The emitter contacts of one group are connected in an electrically conductive way via a metallization; in contrast, the different groups of emitter contacts are not connected in an electrically conductive way among each other or only via an emitter area.

Likewise, the base contacts are divided into groups, wherein each group comprises a number of at least 2 and a maximum of 30, especially a maximum of 20, advantageously a maximum of 10 base contacts. The base contacts of one group connected in an electrically conductive way via a metallization; in contrast, however, the different groups of base contacts are not connected in an electrically conductive way among each other or only via a base area.

Thus, in this advantageous embodiment, only a few base contacts and/or emitter contacts are assembled into one group, however, the fundamental principle of the configuration of the solar cell according to the invention is unchanged. In particular, for this advantageous embodiment, there is only a very low probability that for a fracture of the semiconductor structure, the metallic connection of one group is also broken. As long as the fracture does not damage the metallic connection of one group, in this advantageous embodiment, a fracture also does not result in that significant sub-areas of the solar cell no longer contribute to the power generation.

Also for the advantageous embodiment in which the base contacts and/or emitter contacts are assembled into groups, it is advantageous when the groups have a sufficiently high density on the contacting side of the solar cell.

Advantageously, the groups of the emitter contacts and base contacts are therefore arranged and constructed such that, for each group of emitter contacts, at least this complete group of emitter contacts and at least one complete group of base contacts lie within an imaginary circle with diameter d₃ and for each group of base contacts, at least this complete group of base contacts and at least one complete group of emitter contacts lie within an imaginary circle with diameter d₃, wherein the diameter d₃ is selected such that a condition according to Formula 3 is fulfilled:

d₃≦k₃·\sqrt{Aₖ} (Formula 3),

with a scaling factor k₃ and the surface area A_{K} [cm²] of the contacting side of the solar cell. Studies of the applicant have resulted in that the scaling factor is selected to be advantageously k₃=0.40, preferably k₃=0.26, especially k₃=0.10, more advantageously k₃=0.056.

Also with respect to groups, here and in the following the phrase “complete” means that the entire metallic structure of one group lies within the imaginary circle and not, for example, only a sub-area or center point of the group. The condition according to the imaginary perimeter thus defines a minimum density with respect to the named groups, as well as a maximum with respect to the dimensions of each group.

Furthermore, it is advantageous when the groups of both polarities, i.e., the groups of the emitter contacts among each other and the groups of the base contacts among each other, have a sufficiently high density on the contacting side of the solar cell:

Advantageously, the groups of the emitter contacts are therefore arranged and constructed such that for each group of emitter contacts, at least this complete group of emitter contacts and at least one additional complete group of emitter contacts lie within an imaginary circle with diameter d₄.

Likewise, in this advantageous embodiment, the groups of base contacts are arranged and constructed such that, for each base contact, at least this complete group of base contacts and at least one additional complete group of base contacts lie within an imaginary circle with diameter d₄.

For the two previously named conditions with respect to the groups of emitter contacts and/or base contacts among each other, the diameter d₄ is selected such that a condition according to Formula 4 is fulfilled:

d₄≦k₄·\sqrt{Aₖ} (Formula 4),

with a scaling factor k₄ and the surface area A_{K} [cm²] of the contacting side of the solar cell. Studies of the applicant have resulted in that the scaling factor is advantageously selected as k₄=0.80, preferably k₄=0.51, especially k₄=0.20, more advantageously k₄=0.112.

The previously named advantageous arrangements of the emitter contacts and/or base contacts with respect to the imaginary lattice is likewise advantageous for the arrangement of the previously described groups of the emitter contacts and/or base contacts, wherein, in this case, the groups with a reference point predefined for each groups, such as, for example, the geometric center point of a group, lie on the crossing lines of the imaginary lattices.

Advantageously, the groups of the emitter contacts have, among each other, identical geometries, i.e., the metallic structures have identical constructions with respect to their expansion and geometric dimensions. This likewise applies advantageously for the groups of the base contacts among each other and, in particular, the groups of the emitter contacts advantageously have identical constructions like the groups of the base contacts.

Advantageously, all of the emitter contacts and/or all of the base contacts of the solar cell are constructed and/or arranged according to the previously described structure according to the invention. Likewise, however, it lies in the scope of the invention that only one sub-area of the solar cell, i.e., a part of the emitter contacts and/or base contacts is constructed according to the invention. Advantageously, the sub-area on the contacting side of the solar cell in which the emitter contacts and/or base contacts are constructed according to the invention comprises at least 70%, preferably at least 80%, especially at least 95% of the surface area of the contacting side.

The solar cell according to the invention represents a solar cell that can be contacted on one side. The additional design of the solar cell can here be constructed according to already known solar-cell structures that can be contacted on one side, especially according to the basic design of a back-side contact cell (described, for example, in [1]), the basic design of an emitter-wrap-through solar cell (described, for example, in [2]), or a metal-wrap-through solar cell (described, for example, in [3]).

The emitter of the solar cell according to the invention is advantageously generated by diffusion of a dopant into the semiconductor material. Likewise, however, other methods or structures for the construction of the emitter also lie in the scope of the invention. In particular, the use of aluminum as a doping source for generating a p-doping is advantageous, in connection i) on one hand with a vacuum-deposited aluminum layer as dopant source and ii) on the other hand with printed aluminum-containing pastes. In a subsequent firing step (heating of the structure), it can result in ii) a very complex process profile in which a partially molten layer is present that contains aluminum and silicon and in which solidification forms essentially a eutectic mixture. Simultaneously it results in a doping of the semiconductor with aluminum. This process cannot be attributed solely to diffusion, but instead could also be a result of the solidification of the aluminum/silicon mixture. This formation of the emitter is thus especially advantageous for the construction of a solar cell according to the invention starting from an n-doped semiconductor wafer.

The solar cell according to the invention allows novel types of interconnection for combinations of several solar cells in a solar-cell module:

The invention therefore further comprises a solar-cell module.

The solar-cell module according to the invention comprises at least one first and one second solar cell that are each solar cells according to the invention according to at least one of the previously described embodiments.

The first solar cell is arranged in the solar-cell module next to the second solar cell, wherein as is typical in such modular arrangements, each contacting side is arranged in the module lying underneath.

On the contacting side, a cell connector is arranged that is constructed such that the emitter contacts of the first solar cell are connected in an electrically conductive way to the base contacts of the second solar cell. The solar cells are thus connected in series. Likewise, it lies in the scope of the invention to connect the solar cells in parallel, i.e., the emitter contacts of the first solar cell are connected in an electrically conductive way to the emitter contacts of the second solar cell and likewise the base contacts of the first solar cell are connected in an electrically conductive way to the base contacts of the second solar cell.

Advantageously, the cell connector is flexible, in particular, it has a film-like construction. In this way, the risk that the contact to the cell connector is likewise interrupted for a fracture of a solar cell is also reduced, because the cell connector yields to the movement of individual fracture pieces of the solar cell due to the flexibility of the cell connector during a fracture process. Likewise the use of a non-flexible cell connector lies within the scope of the invention, for example, a cell connector constructed like a circuit board.

Advantageously, the solar-cell module comprises at least two solar cells arranged on next to the other like a row and the cell connector has metallization structures that engage in each other like combs and are arranged such that, for solar cells arranged like rows with the contacting side on the cell connector, the emitter contacts of one solar cell are connected in an electrically conductive way to the base contacts of the adjacent solar cell by means of the comb-like metallization structures. The solar cells are thus connected in series. Likewise it lies in the scope of the invention that the metallization structures engaging in each other like combs are arranged such that the solar cells are connected in parallel.

In one advantageous embodiment of the solar-cell module, the cell connector is constructed as an electrically insulating film that has metallic connection structures on both sides. Thus, in this way, the electrical interconnection on the two sides of the films can be selected independently from each other, in particular, crossing of the conductive paths is also possible.

The metallic connection structure of one side of the cell connector is guided onto the other side via recesses of the film and recesses of the metallic connection structure of the opposite side.

The cell connector is constructed such that the film has a first metallic connection structure on the side facing the solar cell for modular interconnection and a second metallic connection structure on the side facing away from the solar cell and the second metallic connection structure is guided through recesses of the film and the first metallic connection structure to the other side.

Advantageously, the second metallic connection structure is guided via solder or conductive adhesive in the described recesses to the other side. The first metallic connection structure is advantageously likewise pre-allocated with solder or conductive adhesive, in order to provide an electrically conductive connection to the solar cell.

The metallic connection structures are arranged such that, for solar cells arranged with the connecting side on the film, the base contacts of the solar cells are each connected in an electrically conductive way via the recesses to the one metallic connection structure and the emitter contacts of the solar cells are each connected in an electrically conductive way to the other metallic connection structure or vice versa.

For simpler component insertion and handling of the solar cells set on the cell connector, it is advantageous when the cell connector has recesses for the application of a vacuum for the component insertion of the cell connector with solar cells.

Here, the solar cells are placed with the contacting side on the corresponding side of the cell connector and on the side of the cell connector opposite the solar cell, a vacuum is established via the recesses, so that the solar cell is suctioned onto the cell connector. In this way, a simple handling of the cell connector is possible together with the solar cell for the production of the solar-cell module. Likewise, a conductive adhesive for the electrical connection of the emitter contacts and base contacts with the metallic structures of the cell connector could be previously deposited on the cell connector and/or the metallic contacts of the solar cell and after component insertion of the cell connector, the application of the vacuum leads to a contact pressure between the cell connector and contacting side of the solar cell, so that a qualitatively high-quality connection is established by means of the conductive adhesive.

Alternatively, in another advantageous embodiment, another connection technology could also be selected, such as, for example, soldering. For this purpose, the cells and/or the cell connector are supplied with solder appropriately in advance and then soldered.

In another advantageous embodiment, the cell connector is constructed as a field from electrically conductive wires arranged essentially in parallel and solar cells are arranged on the wires such that the emitter contacts of one solar cell are connected in an electrically conductive way by the wires to the base contacts of the adjacent solar cell. The connection of the wires to the contacts is realized advantageously via bonding with conductive adhesive, solder, or welding. Likewise, it lies in the scope of the invention to generate a parallel circuit by connecting the contacts of the same polarities of adjacent solar cells.

### BRIEF DESCRIPTION OF THE DRAWINGS

Other preferred features and embodiments of the solar cell according to the invention and the solar-cell module according to the invention are described below with reference to the figures. Shown each in schematic representation herein are:

FIG. 1, the contacting side of one embodiment of a solar cell according to the invention,

FIG. 2, a section perpendicular to the plane of the drawing in FIG. 1 on the section line designated with A, wherein only one sub-area of the section figure is shown, comprising an emitter contact and a base contact,

FIG. 3, three solar cells according to FIG. 1 that are connected to cell connectors,

FIG. 4, the contacting side of a second embodiment of a solar cell according to the invention in each of which six emitter contacts and six base contacts are assembled into groups,

FIG. 5, a partial cutout of a contacting side of a third embodiment of a solar cell according to the invention in each of which five emitter contacts and five base contacts are assembled into groups,

FIG. 6, a partial cutout of the contacting side of a fourth embodiment of a solar cell according to the invention in which, for the base contacts on one side, and for the emitter contacts on the other side, a lattice with diamond-shaped lattice elements is predetermined and the contacts are each arranged on the crossing points of the lattice lines,

FIG. 7, the contacting side of a fifth embodiment of a solar cell according to the invention in each of which six emitter contacts and six base contacts are assembled into groups,

FIG. 8, the contacting side according to FIG. 4, wherein several types of electrical contacting of the individual groups of contacts by cell connectors are shown,

FIG. 9, the contacting side according to FIG. 7, wherein straight-lined cell connectors for the electrical contacting of the groups of emitter contacts on one side and groups of base contacts of base contacts on the other side are shown,

FIG. 10, an embodiment of a modular interconnection of solar cells according to the invention by a wire field,

FIG. 11, an embodiment of a cell connector for modular interconnection, wherein the cell connector is constructed as a flexible film and has metal structures engaging in each other like combs on the side facing the solar cells,

FIG. 12, an embodiment of a cell connector for modular interconnection with recesses for vacuum suctioning during the module production,

FIG. 13, an embodiment of a cell connector for modular interconnection, wherein the cell connector is constructed as an insulating film that has metallic structures on both sides,

FIG. 14, an exemplary arrangement of the cell connector from FIG. 3 in a solar-cell module, and

FIG. 15, a section perpendicular to the plane of the drawing in FIG. 13a along the line B.

### DETAILED DESCRIPTION OF THE PREFERRED EMBODIMENTS

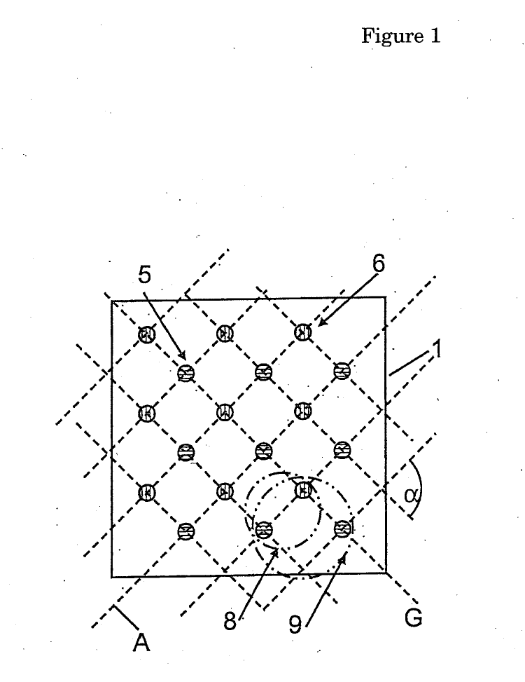

The solar cell shown in FIG. 1 as an embodiment is constructed as a back-side contact cell that was produced from a block silicon wafer with a square surface area. Accordingly, the solar cell has a square contacting side 1. The angle α between two lattice lines equals 90° accordingly. Likewise, constructions with lattices with diamond-shaped elements lie in the scope of the invention in which the angle α is selected as less than 90°.

The embodiment of the solar cell according to the invention has an n-doped base. Accordingly, in FIG. 1, on the contacting side 1, there are several metallic emitter contacts (shown with vertical stripes, an emitter contact is designated, as an example, with reference symbol 5) and metallic base contacts (shown with horizontal stripes, a base contact is designated, as an example, with reference symbol 6).

FIG. 1 is merely a schematic diagram. Typically, a solar cell according to the invention has an edge length of 10 to 20 cm and the distance between an emitter contact and base contact equals less than 5 mm, so that there is a significantly higher density of metallic contacts, as shown in FIG. 1. Likewise, however, the solar cell according to the invention is also advantageous in smaller dimensions, for example, in order to construct the solar cell according to the invention as a concentrator solar cell for use with radiation concentrators.

The emitter contacts and base contacts are arranged on the crossing points of an imaginary, right-angle lattice G that is shown dotted in FIG. 1. Emitter contacts and base contacts here alternate along each line of the imaginary lattice. In addition, the lattice is arranged such that the lattice lines are at an angle of 45° to the edges of the contacting side.

In FIG. 1, two imaginary circles 8 and 9 are also shown dashed for illustrating the conditions listed above for the arrangement and construction of the emitter contacts and/or base contacts.

The circle 9 comprises two emitter contacts (shown with vertical stripes). For the diameter of the circle 9, the contacting side shown in FIG. 1 thus fulfills the conditions that, for each emitter contact, these emitter contacts lie within a circle with the shown diameter and also another emitter contact lies within this circle, wherein both emitter contacts lie completely, i.e., with respect to the entire extent of their metallic structure, within the circle 9. The identical condition also applies for the base contacts, i.e., around each base contact in FIG. 1, an imaginary circle with the diameter of the circle 9 can be arranged such that this base contact and at least one other base contact lie completely in this circle.

Accordingly, the circle 8 illustrates the condition that for an emitter contact (shown with vertical stripes), at least one base contact (shown with horizontal stripes) lies within a circle with the diameter of the circle 8, wherein the emitter contact and base contact each lie completely within this circle. An analogous condition applies for the base contacts.

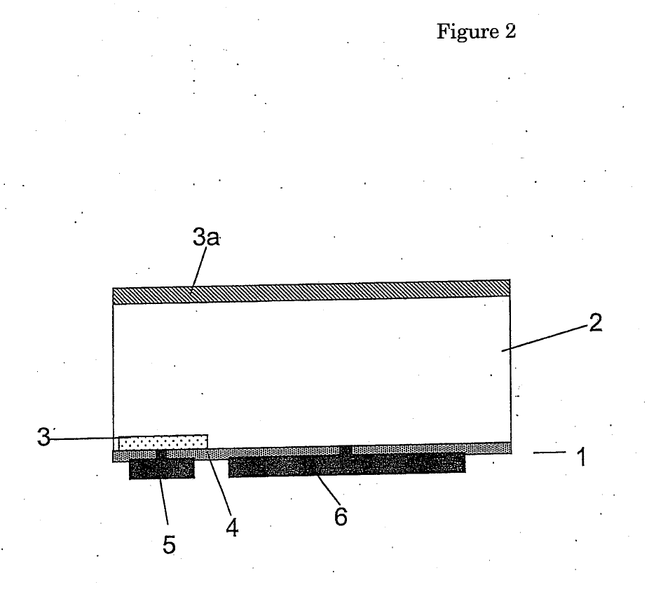

FIG. 2 represents a section perpendicular to the plane of the drawing on the section line A shown in FIG. 1, wherein only one sub-area comprising one emitter contact and one base contact is shown.

The solar cell according to the invention is formed of an n-doped silicon wafer and thus has an n-doped base area 2. An emitter area 3 that is p-doped was generated by diffusion on the contacting side 1. Another p-doped emitter area 3a was generated by means of diffusion on the front side over the entire surface. This emitter area 3a, however, is not connected to the metallic emitter contacts, it is used only for improving the recombination properties of the front side of the solar cell. Alternatively, for improving the recombination properties of the front side of the solar cell, a so-called “front surface field” is advantageous, i.e., instead of the emitter area 3a, an n-doped area that has a significantly higher doping concentration compared with the base.

The light coupling is carried out across the front side in the solar cell according to the invention. Likewise, light can penetrate into the solar cell via the back side, especially re-reflected IR radiation.

An electrically non-conductive insulation layer 4 that is constructed as a silicon-dioxide layer is deposited on the silicon wafer on the contacting side 1 of the solar cell according to the invention. This insulation layer 4 has recesses that are penetrated by the metallic emitter contacts and base contacts.

Alternatively, a construction of the insulation layer from silicon nitride, aluminum oxide, silicon carbide, or as a multi-layer system from the mentioned materials is also advantageous, especially also containing amorphous silicon.

In FIG. 2, as an example, two recesses of the insulation layer 4 and correspondingly a metallic emitter contact 5 and a metallic base contact 6 are shown.

The recesses of the insulation layer 4 are approximately circular (perpendicular to the plane of the drawing in FIG. 1b) and have a surface area of approximately 0.1 mm² on the semiconductor surface. The metallic contacts 5 and 6 pass through the recesses of the insulation layer 4 for contacting the emitter 3 on one hand and the base 2 on the other hand. The surface between the metallic contact and semiconductor surface thus likewise equals approximately 0.1 mm² for each metallic contact.

On the side of the insulation layer facing away from the semiconductor, the metallic contacts cover a surface area that corresponds at least to the surface area between the metallic contact and semiconductor.

Advantageously, however, the metallic contacts on the side of the insulation layer facing away from the semiconductor cover a larger surface area of the insulation layer. Also here, the metallic contacts have an approximately circular shape and cover a surface area of advantageously at least 1 mm², especially at least 5 mm², furthermore at least 10 mm².

In this way it is guaranteed that, due to the, for example, 1 mm² large surface area of the metallic contacts, a permanent connection can be achieved with a cell connector for a simultaneously low output resistance.

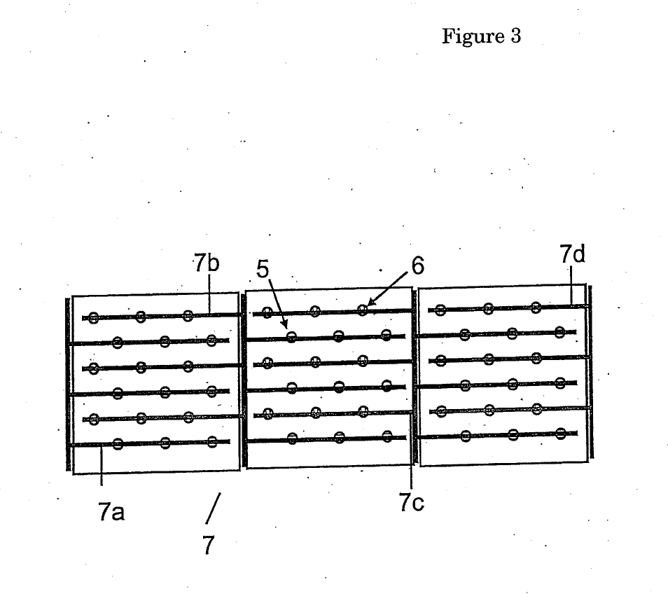

In FIG. 3, a cell connector for the construction of an embodiment of a solar-cell module according to the invention is shown. The cell connector 7 has four comb-like structures 7a to 7d that have a comb-like, interdigitated construction.

The dashed lines in FIG. 3 indicate the positions at which three solar cells according to FIG. 1 are placed with the contacting side on the cell connector 7. Here, for example, through the comb-like metallization structure 7b, an electrically conductive connection to the base contacts of the solar cell arranged on the left is formed, while the right side of the comb-like metallization structure 7b has an electrically conductive connection to the emitter contacts of the solar cell arranged in the middle, so that the base contacts of the solar cell arranged on the left are connected via the cell connector in an electrically conductive way to the emitter contacts of the solar cell arranged in the middle. The same applies with respect to the comb-like metallization structure 7c and the solar cell arranged in the middle with the solar cell arranged on the right.

The comb-like metallization structures 7a and 7d represent termination connections for each end of a solar-cell row, with each connection being connected to external circuits or other solar-cell rows (so-called “strings”).

FIG. 3 is also only one schematic diagram of a cell connector. Typically, a larger number of solar cells are arranged in a row, for example, 15 to 20 solar cells in a row in which the base contacts of one solar cell are connected to each other in an electrically conductive way to the emitter contacts of the adjacent solar cell by comb-like metallization structures 7d, 7c.

The cell connector 7 shown in FIG. 3 advantageously has (not shown) recesses. For the production of a solar-cell module according to the invention, initially conductive adhesive is deposited on the emitter contacts and base contacts point by point. Then the solar cells are moved with the contacting side onto the cell connector according to the positions shown with dashed lines in FIG. 2 and a vacuum is applied by means of the recesses, so that the solar cells are pressed onto the cell connector 7 and accordingly a qualitatively high-quality connection is constructed between the emitter contacts and base contacts by the conductive adhesive to the comb-like metallic structures. Likewise, the connection of the emitter contacts and base contacts with other methods lies in the scope of the invention, such as, for example, by soldering, welding, or alloying.

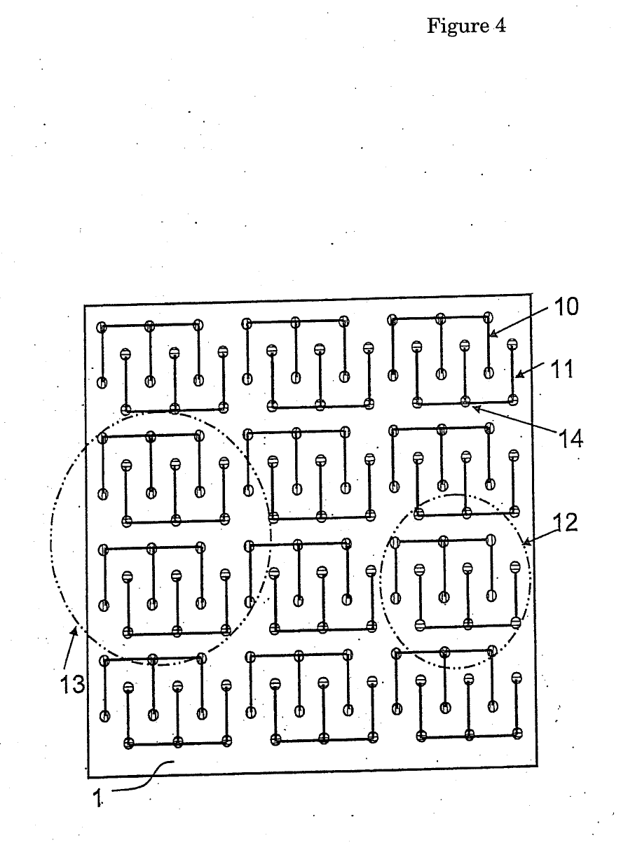

In FIG. 4, one embodiment of the solar cell according to the invention is shown in which, on the contacting side, 6 base contacts are combined into a group of base contacts 10, wherein the individual base contacts are connected to each other in an electrically conductive way by a comb-like metallic structure.

Likewise, 6 emitter contacts are combined into a group of emitter contacts 11, wherein the individual emitter contacts are connected to each other in an electrically conductive way by a comb-like metallic structure.

In FIG. 4, analogous to FIG. 1, two imaginary circles 12 and 13 are shown with dashed lines for illustrating the conditions with respect to the arrangement and construction of the groups of contacts by fixing a maximum diameter of such circles:

The circle 12 represents an example in which, within a circle around a group of emitter contacts (shown with vertical stripes), at least one group of base contacts (shown with horizontal stripes) lies, wherein both groups of contacts lie completely within the circle 12.

Accordingly, the circle 13 illustrates the condition that, within the circle 13, a group of emitter contacts and at least one other group of emitter contacts each lie completely. Likewise, one group of base contacts and at least one other group of base contacts each lie completely in another circle with this diameter, wherein, in the illustrated case, both circles are identical for the selected groups.

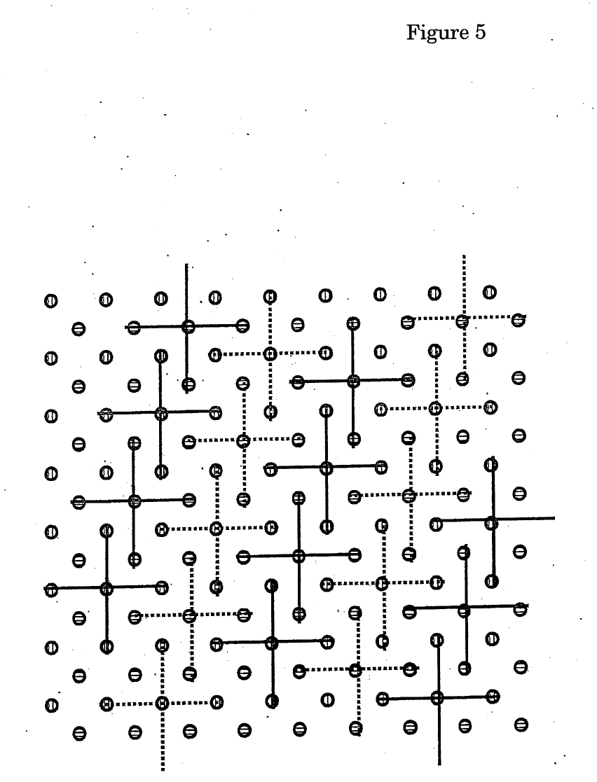

In FIG. 5, a cutout of a contacting side is shown, wherein emitter contacts and base contacts are arranged analogous to FIG. 1 and FIG. 4. In FIG. 5, however, another example for the formation of groups of emitter contacts and base contacts is shown:

Every five emitter contacts are combined by a cross-like metal structure into a group (solid line) and likewise every five base contacts are combined by a cross-like metal structure into a group (dotted line).

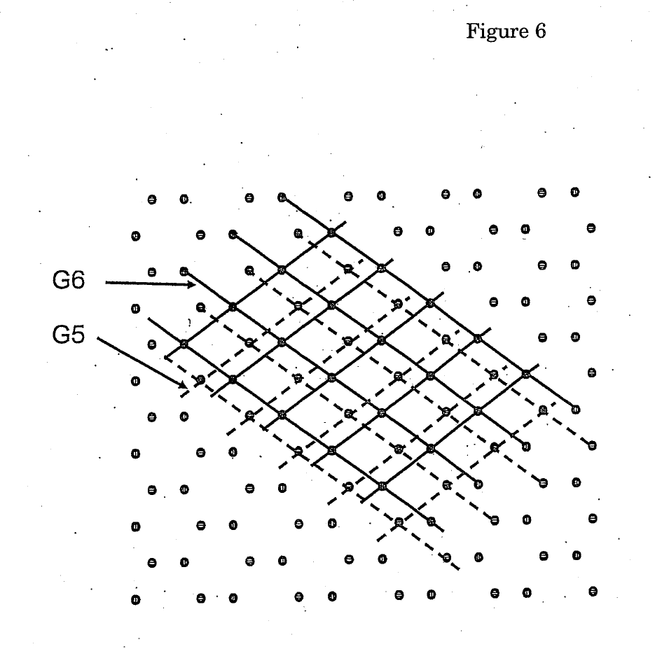

In FIG. 6, another embodiment of a contacting side with a different arrangement of the emitter contacts and base contacts relative to each other is shown.

For this purpose, two imaginary lattices G5 (dashed lines) and G6 (solid lines) were defined that each have diamond-shaped lattice elements. The emitter contacts each lie on the crossing points of the lattice G5 and the base contacts each lie on the crossing contacts of the lattice G6.

The imaginary lattices G5 and G6 are pushed against each other, so that a hexagonal distribution of the emitter contacts and base contacts is produced.

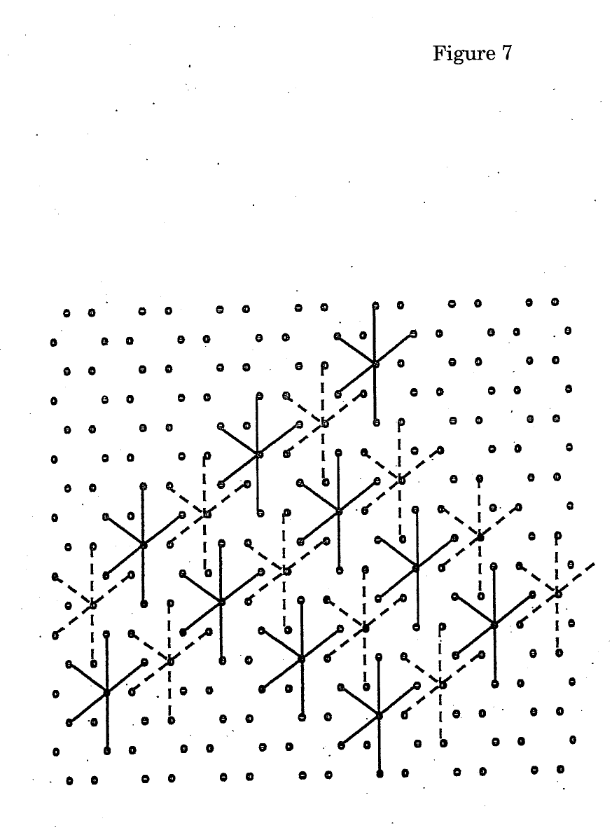

In FIG. 7, an embodiment is shown that has an arrangement of emitter contacts and base contacts according to FIG. 6. Here, however, every six emitter contacts are connected into a group by crow's feet-like metallic connection structures (shown dashed) and every six base contacts are likewise connected into a group by the crow's foot-like connection structures shown in solid lines.

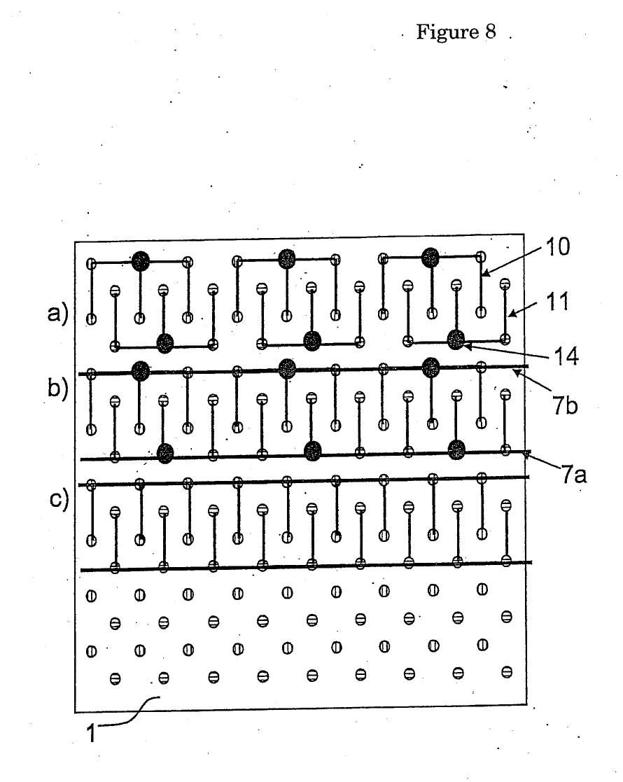

In FIG. 8 it is shown how a contacting side according to FIG. 4 is connected in an electrically conductive way by cell connectors.

Advantageously, initially a conductive adhesive point (designated with reference symbol 14 as an example) is deposited in the middle in each comb-like metallic structure of the groups of emitter contacts and base contacts (10 and 11). This is shown in the first line a) in FIG. 8.

Then, as shown in line b), linear cell connectors 7a and 7b are placed above the comb-like metallization structures of the individual groups and the conductive adhesive points, so that, at the conductive adhesive points, there is an electrically conductive connection between the comb-like metallization structures and the cell connectors. The linear cell connector 7b thus contacts the base contacts and the linear cell connector 7a contacts the emitter contacts of the contacting side shown in FIG. 8.

Alternatively, it is possible, as shown in line c), to connect the linear cell connector via the entire contact surface to the metallic comb-like structures, for example, by bonding, soldering, or welding.

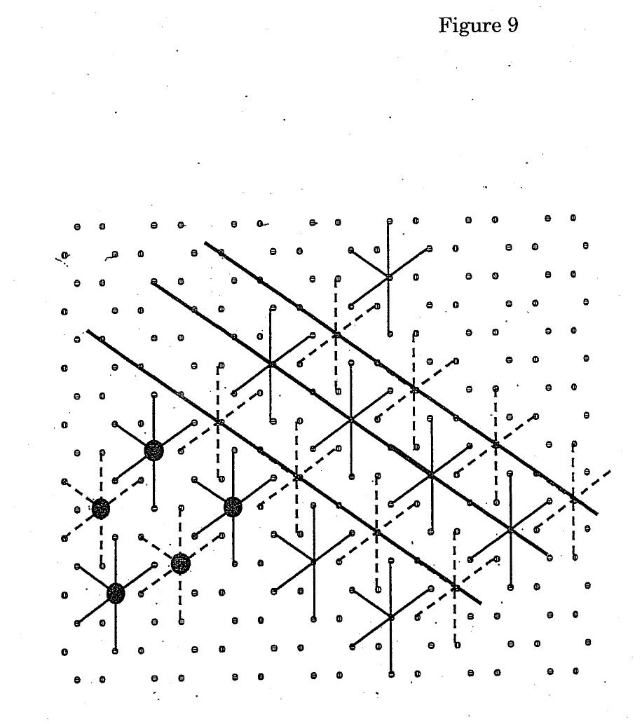

In FIG. 9 it is shown that the contacting side shown in FIG. 7 can likewise be connected by linear cell connectors, wherein the linear cell connectors alternately connect in an electrically conductive way emitter contacts and base contacts or the metallization structures of the groups of emitter contacts and base contacts.

Advantageously, for this purpose, in the middle on the crow's foot-like metallic connection structures, points with conductive adhesive are deposited by which the cell connectors are connected in an electrically conductive way to the metallic crow's foot-like connection structures. Such points are shown in FIG. 9 as examples by the filled circles.

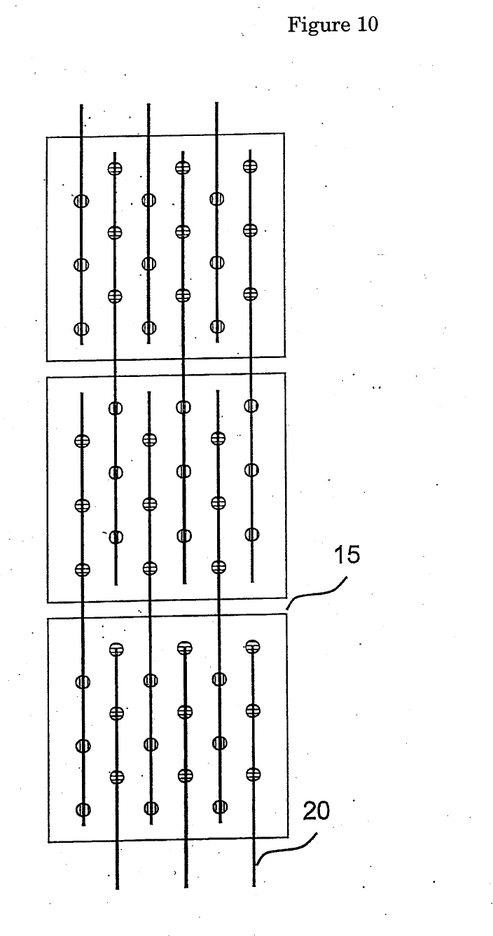

In FIG. 10, an embodiment of a modular interconnection is shown in which the solar cells (one solar cell is designated with 15 as an example) are connected by a wire field. For this purpose, individual linear wires are arranged such that the base contacts of one solar cell are connected in an electrically conductive way to the emitter contacts of an adjacent solar cell. As an example, a wire 20 is designated. For the production of a module, the wire field and the contacts of the solar cells are pre-soldered or provided with conductive adhesive and connected to each other. Advantageously, the wire field is arranged on a carrier formed advantageously from the material EVA.

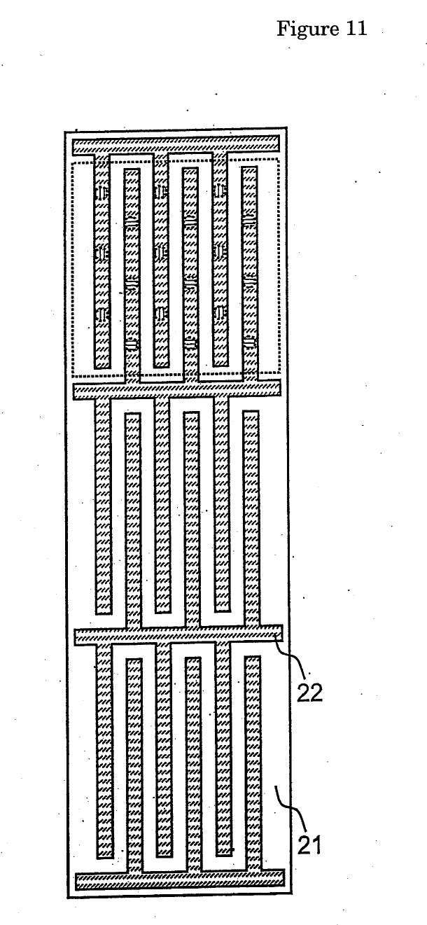

In FIG. 11, an embodiment of a cell connector is shown that is constructed as a flexible, electrically insulating film 21 and has comb-like, interdigitated metal structures 22 on one side and on the side facing the solar cells. The arrangement of a solar cell on the cell connector is shown as an example by dashed lines. Advantageously, an electrically non-conductive filler material is arranged on the flexible film between the comb-like metal structures, with this filler material preventing the formation of air bubbles between the solar cell and flexible film 21.

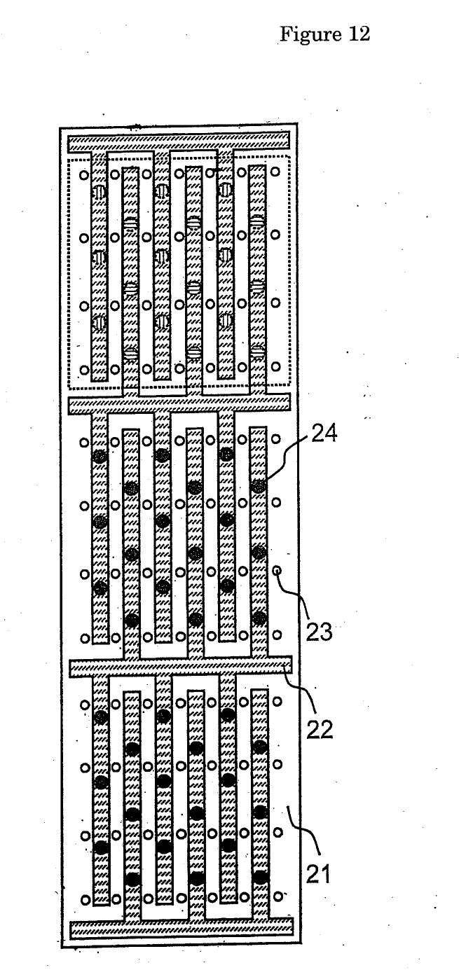

In FIG. 12, a refinement of the cell connector from FIG. 11 is shown that has additional recesses 23, so that by applying a vacuum on the side facing away from the solar cells through the recesses, the solar cells can be drawn to the cell connectors. Advantageously, the cell connector is pre-soldered at points 24 on the metal structures or provided with conductive adhesive, wherein the points are arranged such that for the application of a solar cell on the cell connector, the pre-soldered points contact the emitter contacts or base contacts. The arrangement of a solar cell is indicated as an example by the dashed line.

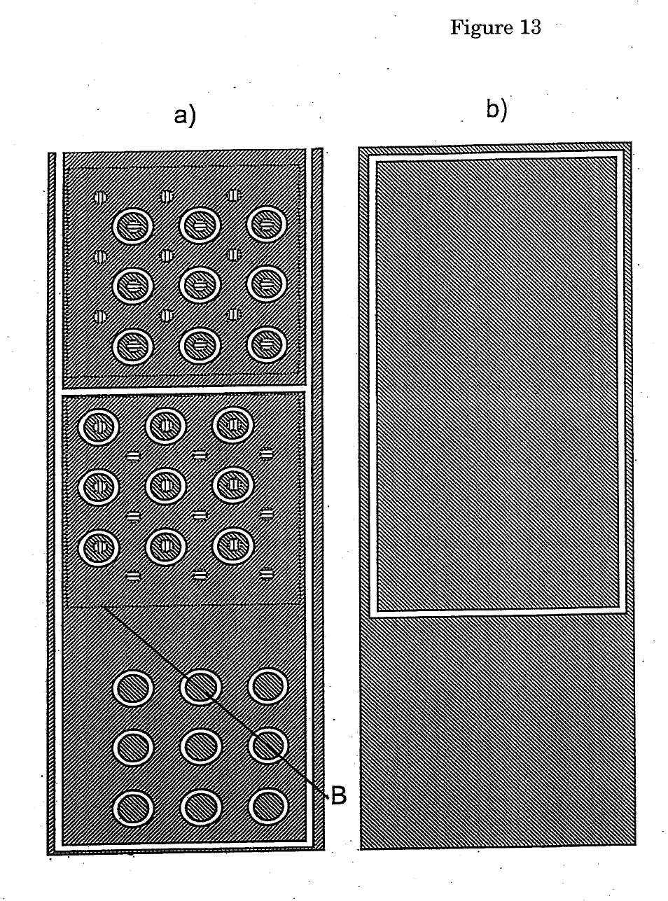

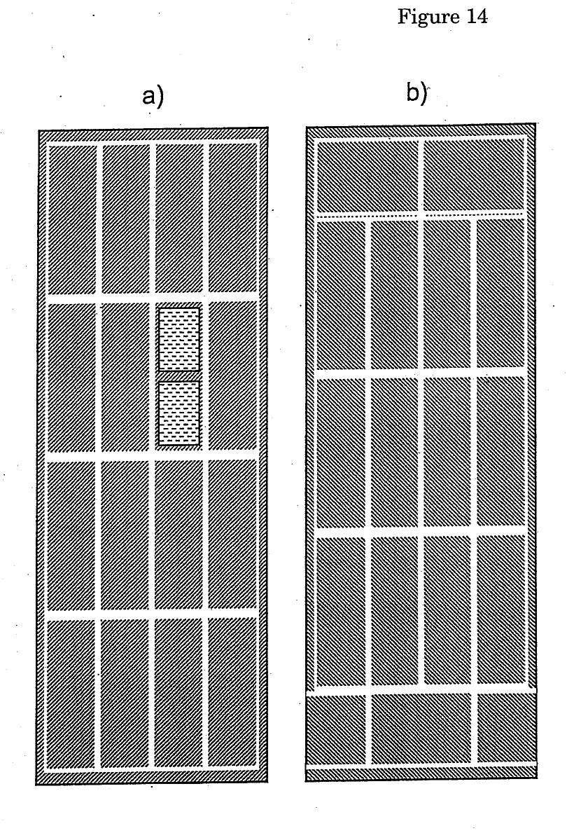

In FIG. 13, one embodiment of a cell connector is shown that is constructed as an electrically insulating, flexible film 26 that has a first metallization on the side facing the solar cells and a second metallization on the side facing away from the solar cells. The side facing the solar cells is shown in FIG. 13a and the side facing away from the solar cells is shown in FIG. 13b. The flexible film and the first metallization have recesses 25 at which the second metallization is guided through the recesses to the side facing the solar cells. In FIG. 13a, shown with dashed lines as an example, the position of a solar cell is shown. The metallizations and the recesses are arranged such that the first metallization covers the base contacts and the second metallization through the recesses covers the emitter contacts of the solar cell and each are connected in an electrically conductive way. In FIG. 13b, it is visible that the cell connector on the side facing away from the solar cells is divided into individual areas separated from each other electrically. This allows a series interconnection of the solar cells in the module, as described below with reference to FIG. 14:

In FIG. 14, an example arrangement of the cell connector from FIG. 13 in a solar-cell module is shown, wherein FIG. 14a shows the side facing the solar cells and FIG. 14b shows the side facing away from the solar cells. In FIG. 14a, the arrangement of two solar cells is shown as an example.

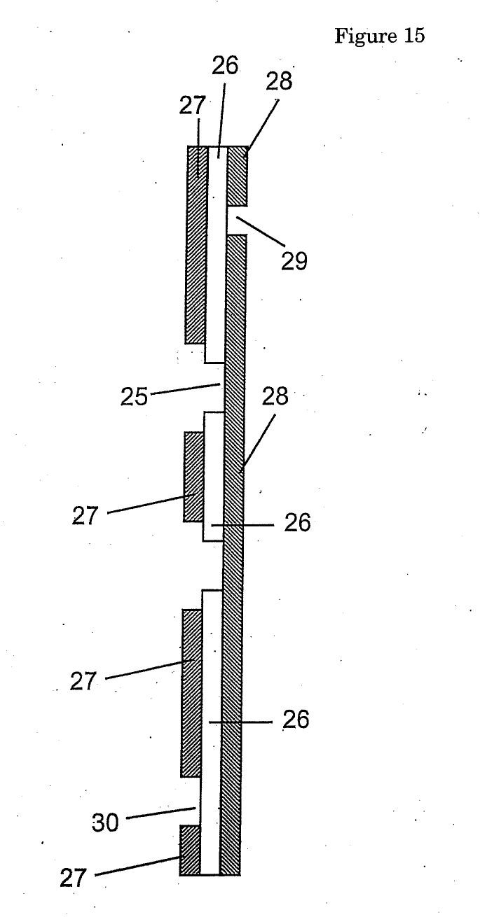

FIG. 15 shows a section figure of the cell connector perpendicular to the plane of the drawing in FIG. 13 along the line B. The electrically insulating, flexible film 26 is partially covered on the side facing the solar cells (shown at the top) with a first metallization 27 and partially covered on the side facing away from the solar cells with a second metallization 28. In recesses 25 both of the first metallization and also of the flexible film, the second metallization can be guided to the side facing the solar cells or an electrically conductive contact with the solar cells can be established by means of conductive adhesive or solder. Furthermore, recesses 29 of the second metallization and 30 of the first metallization are shown that create a structuring of the metallizations according to FIGS. 13 and 14.

### REFERENCES

[1] Lammert, M. D. and R. J. Schwartz (1977) “The Interdigitated Back Contact Solar Cell: A Silicon Solar Cell for Use in Concentrated Sunlight” Transactions on Electron Devices ED-24 (4): 337-42

[2] Gee, J. M., W. K. Schubert, et al. (1993) “Emitter wrap-through solar cell” Proceedings of the 23rd IEEE Photovoltaic Specialists Conference, Louisville, Ky., USA, IEEE, New York, N.Y., USA

[3] Van Kerschaver, E., S. De Wolf, et al. (2000) “Towards back contact silicon solar cells with screen printed metallisation” Proceedings of the 28^{th} IEEE Photovoltaics Specialists Conference, Anchorage, Ak., USA

1. Solar cell for interconnection in a solar-cell module, comprising at least one metallic base contact (6), at least one metallic emitter contact (5), and a semiconductor structure that has at least one base area and at least one emitter area (2, 3),
wherein the base area and emitter area (2, 3) have opposite doping types and border each other at least partially for formation of a pn-junction,
the base contact (6) is connected in an electrically conductive way to the base area (2) and the emitter contact (5) is connected in an electrically conductive way to the emitter area (3), and
both the base contact and the emitter contact (6, 5) are arranged on one contacting side (1) of the solar cell,
wherein several of the metallic emitter contacts (5) are each connected in an electrically conductive way to the emitter area (3) and several of the metallic base contacts (6) are each connected in an electrically conductive way to the base area (2),
the emitter contacts are not connected among each other or are exclusively connected by the emitter area (3), in an electrically conductive way, and
the base contacts (6) are not connected among each other or are exclusively connected by the base area (2), in an electrically conductive way.

2. Solar cell according to claim 1, wherein the emitter contacts (5) are each arranged and constructed such that, around each of the emitter contacts (5), an imaginary convex surface area is defined that completely contains the emitter contact and contains none of the base contacts (6) and also no sub-area of a base contact, and the base contacts (6) are each arranged and constructed such that, around each of the base contacts (6), an imaginary convex surface area is defined that completely contains the base contact (6) and contains none of the emitter contacts (5) and also no sub-area of an emitter contact (5).

3. Solar cell according to claim 1, wherein the solar cell has at least 10 of the emitter contacts and at least 10 of the base contacts (5, 6).

4. Solar cell according to claim 1, wherein the emitter contacts and the base contacts (5, 6) are arranged and constructed such that for each of the emitter contacts (5) it is valid that at least a complete one of the emitter contacts (5) and at least a complete one of the base contacts (6) lie within an imaginary circle (8) with diameter d₁ and for each of the base contacts (6) it is valid that at least a complete one of the base contacts (6) and at least a complete one of the emitter contacts (5) lie within an imaginary circle (8) with diameter d₁,
wherein the diameter d₁ fulfills the following condition according to Formula 1:
d₁≦k₁·\sqrt{Aₖ} (Formula 1),
with a scaling factor k₁ and a surface area A_{K} [cm²] of the contacting side (1) of the solar cell and k₁=0.13 to k₁=0.014.

5. Solar cell according to claim 1, wherein at least one of: the emitter contacts (5) are arranged and constructed such that for each of the emitter contacts (5) it is valid that at least a complete one of the emitter contacts (5) and at least one other complete one of the emitter contacts (5) lie within an imaginary circle (9) with diameter d₂, or the base contacts (6) are arranged and constructed such that for each of the base contacts (6) at least a complete one of the base contacts (6) and at least one other complete one of the base contacts (6) lie within an imaginary circle (9) with diameter d₂,
wherein the diameter d₂ fulfills the following condition according to Formula 2:
d₂≦k₂·\sqrt{Aₖ} (Formula 2),
with a scaling factor k₂ and the surface area A_{K} [cm²] of the contacting side (1) of the solar cell and k₂=0.26 to k₂=0.028.

6. Solar cell according to claim 1, wherein the emitter contacts (5) and the base contacts (6) are arranged on crossing points of an imaginary, square lattice (G), wherein the emitter contacts and the base contacts (5, 6) are arranged such that the emitter contacts and the base contacts (5, 6) alternate along each line of the imaginary lattice.

7. Solar cell according to claim 6, wherein the solar cell has a square contacting side (1) and the imaginary lattice (G) is arranged such that lattice lines stand at an angle of 45° relative to edges of the contacting side (1).

8. Solar cell according to claim 7, wherein the emitter contacts (5) among each other and likewise the base contacts (6) among each other have a spacing of less than 1 cm.

9. Solar cell according to claim 1, wherein the emitter contacts and the base contacts (5, 6) are constructed such that each of the contacts covers a total surface area less than 16 mm².

10. Solar cell according to claim 1, wherein on the contacting side (1), the semiconductor structure has an electrically non-conductive insulation layer (4) that has recesses at locations of the base contacts and the emitter contacts (5), and the base contacts and the emitter contacts (6, 5) are arranged on the insulation layer (4) and electrical connections pass through the recesses in the insulation layer (4) for electrical contacting of the semiconductor structure.

11. Solar cell according to claim 10, wherein the recesses of the insulation layer (4) have a surface area less than 16 mm².

12. Solar cell according to claim 11, wherein the base contacts and the emitter contacts (6, 5) on the insulation layer (4) each cover an area with a surface area less than 16 mm².

13. Solar cell according to claim 1, wherein the emitter contacts (5) are divided into groups, wherein each of the groups (11) comprises a number of at least 2 emitter contacts and a maximum of 30, and the emitter contacts (5) of one of the groups are connected in an electrically conductive way via a metallization, whereas the different groups of emitter contacts (11) are not connected or are exclusively connected in an electrically conductive way among each other only via the emitter area (3), and the base contacts (6) are divided into groups (10), wherein each of the group comprises a number of at least 2 base contacts and a maximum of 30, especially a maximum of 20, advantageously a maximum of 10 base contacts and the base contacts (6) of one of the groups (10) are connected in an electrically conductive way via a metallization, whereas the different groups of base contacts (10) are not connected or are exclusively connected in an electrically conductive way among each other only via the base area (2).

14. Solar cell according to claim 13, wherein the groups of the emitter contacts and base contacts (11, 10) are arranged and constructed such that for each group of the emitter contacts (11), at least a complete group of the emitter contacts (11) and at least one complete group of the base contacts (10) lie within an imaginary circle (12) with diameter d₃ and for each group of the base contacts (10), at least a complete group of the base contacts (10) and at least one complete group of emitter contacts (11) lie within an imaginary circle (12) with diameter d₃, wherein the diameter d₃ fulfills the following condition according to Formula 3:
d₃≦k₃·\sqrt{Aₖ} (Formula 3),
with a scaling factor k₃ and the surface area A_{K} [cm²] of the contacting side (1) of the solar cell and k₃=0.40 to k₃=0.056.

15. Solar cell according to claim 14, wherein at least one of: the groups of emitter contacts (11) are arranged and constructed such that for each group of the emitter contacts, at least the complete group of the emitter contacts (11) and at least one other complete group of the emitter contacts lie within an imaginary circle (13) with diameter d₄, or the groups of the base contacts (10) are arranged and constructed such that for each group of the base contacts (10), at least the complete group of the base contacts (10) and at least one other complete group of the base contacts lie within an imaginary circle (13) with diameter d₄,
wherein the diameter d₄ fulfills the following condition according to Formula 4:
d₄≦k₄·\sqrt{Aₖ} (Formula 4),
with a scaling factor k₄ and the surface area A_{K} [cm²] of the contacting side (1) of the solar cell and k₄=0.80 to k₄=0.112.

16. Solar cell according to claim 1, wherein the solar-cell structure corresponds to a basic design of a back-side contact cell (“RCC”) or an emitter-wrap-through solar cell (“EWT”) or a metal-wrap-through solar cell (“MWT”).

17. Solar cell according to claim 1, wherein the solar cell has at least 10 of the emitter contacts and at least 10 of the base contacts (5, 6).

18. Solar cell according to claim 1, wherein the solar cell comprises a sub-area that is at least 70% of a surface area of a contacting side (1) of a larger solar cell.

19. Solar-cell module, comprising at least one first and one solar cell each according to claim 1, and at least one cell connector, wherein the first solar cell is arranged in the solar-cell module next to the second solar cell and the cell connector (7) is arranged and constructed on the contacting side (1) of the first and the second solar cell such that the emitter contacts (5) of the first solar cell are connected in an electrically conductive way to the base contacts of the second solar cell or vice versa.

20. Solar-cell module according to claim 19, wherein the cell connector (7) is constructed as a circuit board or flexibly.

21. Solar-cell module according to claim 20, wherein the solar-cell module comprises at least two solar cells arranged one next to the other in a row, and the cell connector (7) has comb-like, interdigitated metallization structures (7a, 7b, 7c, 7d) that are arranged such that, for the solar cells arranged in the row with the contacting side (1) on the cell connector (7), the emitter contacts (5) of one of the solar cells are connected in an electrically conductive way to the base contacts of the adjacent solar cell via the comb-like metallization structure.

22. Solar-cell module according to claim 20, wherein the cell connector is constructed as an electrically insulating film (21, 26), the film has, on a side facing the solar cell for modular interconnection, a first metallic connection structure (27) and, on a side facing away from the solar cell, a second metallic connection structure (28) and the second metallic connection structure is guided through recesses (25) of the film and the first metallic connection structure to the other side, wherein the metallic connection structures are arranged such that, for solar cells arranged with the contacting side (1) on the film, the base contacts (6) of the solar cells are each connected in an electrically conductive way via the recesses to the one metallic connection structure and the emitter contacts (5) of the solar cells are each connected in an electrically conductive way to the other metallic connection structure.

23. Solar-cell module according to claim 20, wherein the cell connector is constructed as a field of electrically conductive wires arranged essentially parallel and the solar cells are arranged on the wires such that the emitter contacts (5) of one of the solar cells are connected in an electrically conductive way by the wires to the base contacts (6) of the adjacent solar cell.

24. Solar-cell module according to claim 19, wherein the cell connector has recesses (23) for application of a vacuum for component insertion of the cell connector with the solar cells.
